(19) United States
(12) Patent Application Publication
(10) Pub. No.: US 2023/0240046 A1
(43) Pub. Date: Jul. 27, 2023

(54) HEAT SINK AND ELECTRONIC APPARATUS

(71) Applicant: Fujitsu Limited, Kawasaki-shi (JP)

(72) Inventors: Kenji Sasabe, Kawasaki (JP); Hideo Kubo, Kawasaki (JP); Keita Hirai, Kawasaki (JP); Atsushi Endo, Kawasaki (JP); Masahide Kodama, Kawasaki (JP); Nobumitsu Aoki, Kawasaki (JP); Yuki Kanai, Kawasaki (JP); Takashi Urai, Kawasaki (JP)

(73) Assignee: Fujitsu Limited, Kawasaki-shi (JP)

(21) Appl. No.: 17/977,037

(22) Filed: Oct. 31, 2022

(30) Foreign Application Priority Data
Jan. 21, 2022 (JP) 2022-007788

(51) Int. Cl. H05K 7/20

(52) U.S. Cl. CPC H05K 7/2039; H05K 7/20154

(57) ABSTRACT

A heat sink comprises a bottom plate and a plurality of fins. The bottom plate is formed in a T-shape of a head portion and a body portion and includes a coupling region in which the body portion is thermally coupled to a heat generation element; and the plurality of fins that are erected at the head portion and the body portion of the bottom plate and extend in a direction from the head portion toward the body portion. With the plurality of fins, a pressure loss of first air which flows through a center portion of the head portion is smaller than a pressure loss of second air which flows through a side portion of the head portion in a case where air flows between the plurality of fins along the direction.

### CROSS-REFERENCE TO RELATED APPLICATION

This application is based upon and claims the benefit of priority of the prior Japanese Patent Application No. 2022-7788, filed on Jan. 21, 2022, the entire contents of which are incorporated herein by reference.

### FIELD

The embodiments discussed herein are related to a heat sink and an electronic apparatus.

### BACKGROUND

As a technique for cooling a heat generation element, a heat sink thermally coupled to the heat generation element is known. For example, the heat sink includes a plurality of fins, and air flows between the plurality of fins to dissipate heat.

Japanese Laid-open Patent Publication No. 2003-142637, Japanese Laid-open Patent Publication No. 2002-280779, Japanese Laid-open Patent Publication No. 2016-184639, and Japanese Laid-open Patent Publication No. 2003-060135 are disclosed as related art.

### SUMMARY

According to an aspect of the embodiments, a heat sink includes: a bottom plate that is formed in a T-shape of a head portion and a body portion and includes a coupling region in which the body portion is thermally coupled to a heat generation element; and a plurality of fins that are erected at the head portion and the body portion of the bottom plate and extend in a direction from the head portion toward the body portion, wherein with the plurality of fins, a pressure loss of first air which flows through a center portion of the head portion is smaller than a pressure loss of second air which flows through a side portion of the head portion in a case where air flows between the plurality of fins along the direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view of an electronic apparatus according to an embodiment of the technology disclosed herein;

FIG. 2 is a cross-sectional view taken along a line II-II in FIG. 1;

FIG. 3 is a perspective view of a heat sink in FIG. 1;

FIG. 4 is a plan view of the heat sink in FIG. 1;

FIG. 5 is a plan view illustrating a state in which air is supplied to the heat sink in FIG. 1;

FIG. 6 is a plan view of a heat sink according to a first modification example;

FIG. 7 is a plan view of a heat sink according to a second modification example;

FIG. 8 is a plan view of a heat sink according to a third modification example;

FIG. 9 is a plan view of a heat sink according to a fourth modification example;

FIG. 10 is a plan view of a heat sink according to a fifth modification example;

FIG. 11 is a plan view of a heat sink according to a sixth modification example;

FIG. 12 is a two-side diagram of a heat sink according to a seventh modification example;

FIG. 13 is a plan view of a heat sink according to an eighth modification example;

FIG. 14 is a perspective view of a fin according to a ninth modification example;

FIG. 15 is a perspective view of a fin according to a tenth modification example;

FIG. 16 is a longitudinal cross-sectional view of a heat sink according to an eleventh modification example;

FIG. 17 is a plan view of a heat sink according to the eleventh modification example;

FIG. 18 is a plan view illustrating a state in which air is supplied to a heat sink according to a first comparative example; and

FIG. 19 is a plan view illustrating a state in which air is supplied to a heat sink according to a second comparative example.

### DESCRIPTION OF EMBODIMENTS

An object of the technique disclosed in the present application is to provide a heat sink and an electronic apparatus capable of improving cooling performance for a heat generation element, for example, as compared with a heat sink in which air flows while avoiding a coupling region thermally coupled to the heat generation element.

Hereinafter, embodiments of the technique disclosed herein are described.

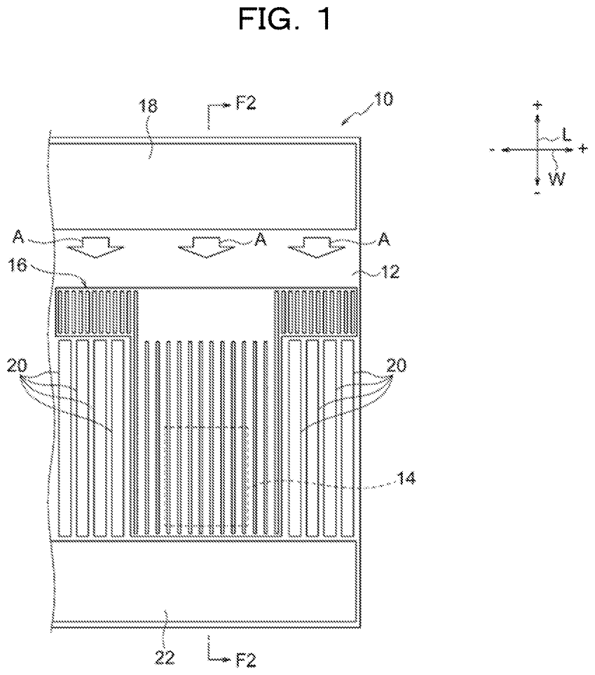

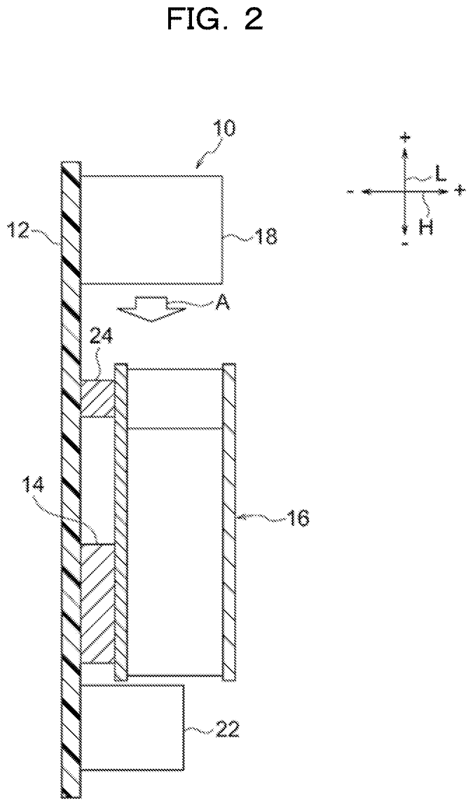

As an example, as illustrated in FIGS. 1 and 2, an electronic apparatus 10 includes a substrate 12, a heat generation element 14, a heat sink 16, a fan 18, a plurality of storage devices 20, an external interface 22, and a power supply device 24. The electronic apparatus 10 is, for example, a server.

As an example, a W direction corresponds to a lateral direction of the electronic apparatus 10, an L direction corresponds to a length direction of the electronic apparatus 10, and an H direction corresponds to a height direction of the electronic apparatus 10. As an example, a + side in the L direction is a front side of the electronic apparatus 10, and a − side in the L direction is a rear side of the electronic apparatus 10. A + side in the H direction is an upper side of the electronic apparatus 10, and a − side in the H direction is a lower side of the electronic apparatus 10.

The substrate 12 extends in the lateral direction and the length direction of the electronic apparatus 10. For example, the substrate 12 is disposed such that the height direction of the electronic apparatus 10 is a thickness direction of the substrate 12. The heat generation element 14 is mounted on the substrate 12. For example, the heat generation element 14 is a central processing unit (CPU). The heat sink 16 is provided above the heat generation element 14. The heat sink 16 is disposed between the fan 18 and the external interface 22. The fan 18 is disposed at a front end portion of the substrate 12. As indicated by an arrow A, the fan 18 sends out air toward a rear end portion of the substrate 12.

The plurality of storage devices 20 are disposed at both sides of the heat generation element 14 in the lateral direction. The storage device 20 is, for example, a dual inline memory module (DIMM). The external interface 22 is disposed at a rear end portion of the substrate 12. For example, the external interface 22 is a Peripheral Component Interconnect (PCI) card. The power supply device 24 is disposed between the heat generation element 14 and the fan 18. The power supply device 24 is disposed below the heat sink 16.

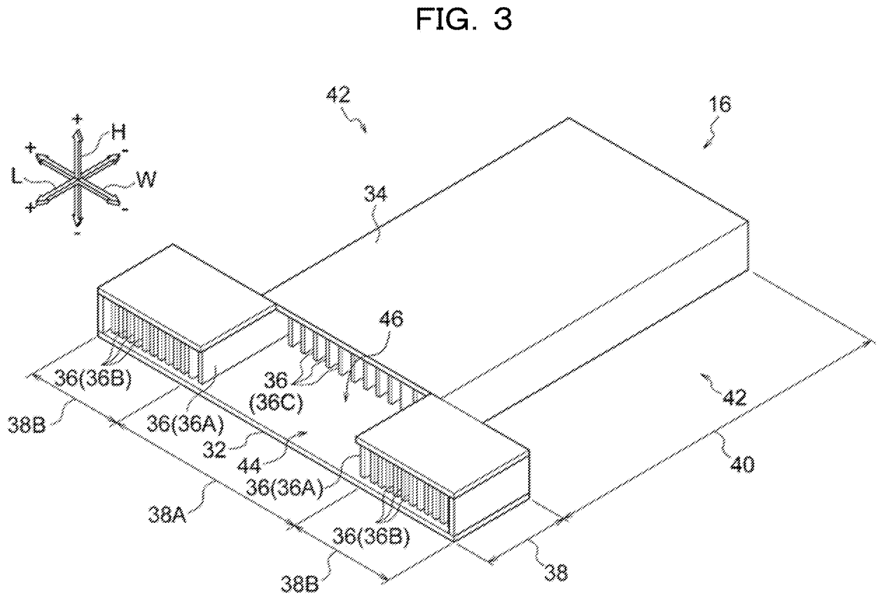

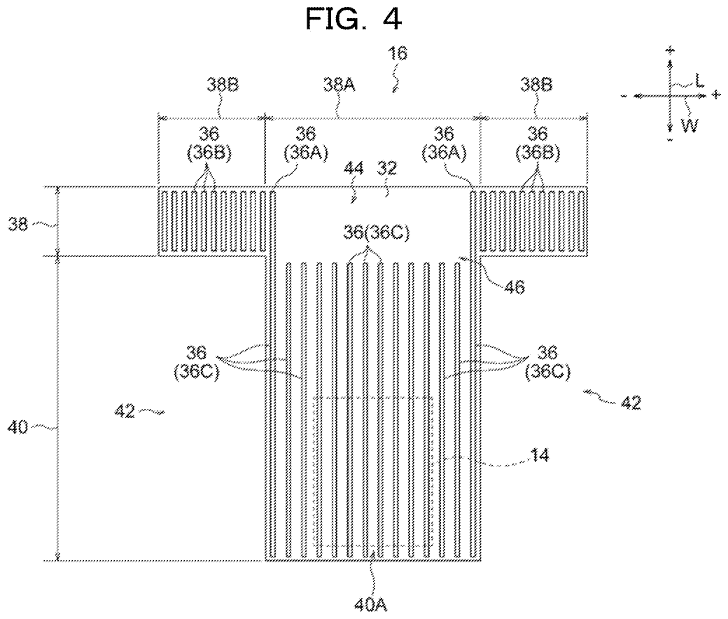

As an example, as illustrated in FIGS. 3 and 4, the heat sink 16 includes a bottom plate 32, a top plate 34, and a plurality of fins 36. The bottom plate 32 is formed in a T-shape having a head portion 38 and a body portion 40. As an example, the heat sink 16 has a configuration symmetrical in the lateral direction. FIGS. 1 and 4 do not illustrate the top plate 34 in order to clarify arrangement of the plurality of fins 36.

The head portion 38 is a front portion of the bottom plate 32, and the body portion 40 is a rear portion of the bottom plate 32 relative to the head portion 38. The head portion 38 includes a center portion 38A and a pair of side portions 38B. A portion obtained by extending the body portion 40 to the front side of the bottom plate 32 is the center portion 38A of the head portion 38. For example, a lateral width of the center portion 38A coincides with a lateral width of the body portion 40. Each side portion 38B projects toward both sides of the bottom plate 32 in the lateral direction with respect to the body portion 40.

The body portion 40 includes a coupling region 40A thermally coupled to the heat generation element 14. The coupling region 40A is located on a rear side than a center portion in the body portion 40 in a longitudinal direction. The longitudinal direction of the body portion 40 corresponds to a direction from the head portion 38 toward the body portion 40. External regions 42 on both sides of the body portion 40 in the lateral direction are regions in which the plurality of storage devices 20 (see FIG. 1) described above are disposed. For example, the plurality of storage devices 20 are disposed at the both sides of the body portion 40 in the lateral direction.

In the same manner as the bottom plate 32, the top plate 34 is formed in a T-shape. The plurality of fins 36 are erected at the bottom plate 32. Lower end portions of the plurality of fins 36 are coupled to the bottom plate 32, and upper end portions of the plurality of fins 36 are coupled to the top plate 34. The plurality of fins 36 are arranged in the lateral direction of the electronic apparatus 10 (for example, the lateral direction of the T-shaped bottom plate 32). Each of the plurality of fins 36 extends in a forward-rearward direction of the electronic apparatus 10 (for example, a longitudinal direction of the T-shaped bottom plate 32). The longitudinal direction of the bottom plate 32 corresponds to a direction from the head portion 38 toward the body portion 40.

As illustrated in FIG. 4 as an example, for example, the plurality of fins 36 are respectively erected at the center portion 38A of the head portion 38, each side portion 383 of the head portion 38, and the body portion 40. Hereinafter, in a case where the plurality of fins 36 are distinguished from each other, the fin 36 erected at the center portion 38A of the head portion 38 is referred to as a center portion fin 36A, the fin 36 erected at the side portions 38B of the head portion 38 is referred to as a side portion fin 36B, and the fin 36 erected at the body portion 40 is referred to as a body portion fin 36C.

A notch 44 in a rectangular shape is formed at the plurality of fins 36. The notch 44 is formed at the plurality of fins 36 at the center portion 38A of the head portion 38. By forming the notch 44 at the plurality of fins 36 at the center portion 38A of the head portion 38, the center portion fins 36A are provided at the center portion 38A of the head portion 38, and the number of the center portion fins 36A is smaller than the number of a plurality of body portion fins 36C. For example, a pair of center portion fins 36A are provided at the center portion 38A of the head portion 38. The pair of center portion fins 36A are disposed at both end portions of the center portion 38A (for example, portions on the side of each side portion 38B of the center portion 38A). The notch 44 is formed between the pair of center portion fins 36A arranged at the both end portions of the center portion 38A.

The pair of center portion fins 36A are formed continuously with the body portion fins 36C at both ends among the plurality of body portion fins 36C. Among the plurality of body portion fins 36C, front end portions of the remaining body portion fins 36C excluding the body portion fins 36C at the both ends terminate at a front end of the body portion 40.

An interval between the pair of center portion fins 36A is wider than an interval between a plurality of side portion fins 36B. The interval between the plurality of side portion fins 36B is narrower than an interval between the plurality of body portion fins 36C. The intervals between the plurality of side portion fins 36B are the same, and the intervals between the plurality of body portion fins 36C are also the same. As an example, the center portion fins 36A, the side portion fins 36B, and the body portion fins 36C respectively have the same width, and the center portion fins 36A, the side portion fins 36B, and the body portion fins 36C also respectively have the same height.

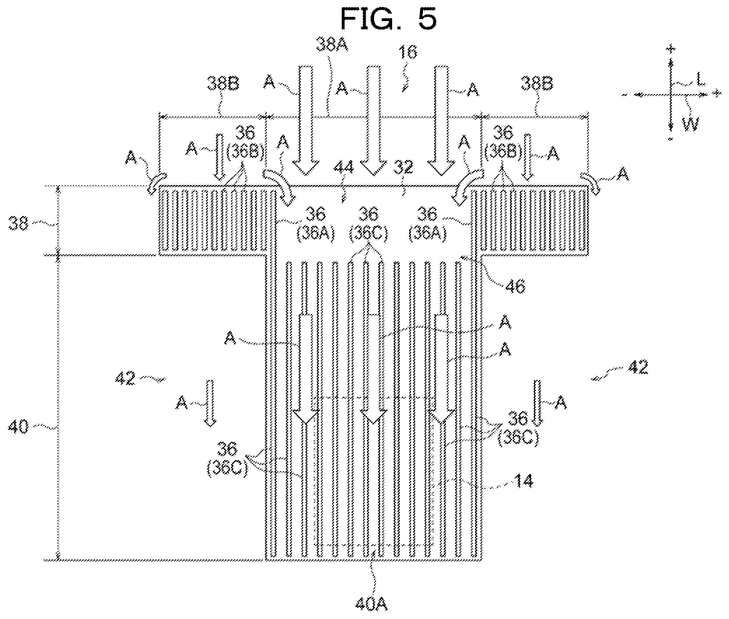

FIG. 5 illustrates a state in which air is supplied to the heat sink 16. Arrows A indicate a direction of a flow of air. As a length of the arrow A is increased, a flow velocity is increased, and as a width of the arrow A is increased, a flow rate is increased.

As an example, as illustrated in FIG. 5, air is supplied to the heat sink 16 from a front side of the heat sink 16. Most of the air supplied to the heat sink 16 from the front side of the heat sink 16 flows along a longitudinal direction of the bottom plate 32 from the head portion 38 side between the plurality of fins 36. A part of the air supplied from the front side of the heat sink 16 to the heat sink 16 flows along the longitudinal direction of the bottom plate 32 through both sides of the heat sink 16 in the lateral direction. The air passing through each side portion 38B of the head portion 38 flows through the external regions 42 on the both sides of the body portion 40 in the lateral direction along the longitudinal direction of the bottom plate 32.

As described above, the notch 44 is formed in the plurality of fins 36 at the center portion 38A of the head portion 38. The pair of center portion fins 36A are disposed at both end portions of the center portion 38A of the head portion 38, and the interval between the pair of center portion fins 36A is wider than the interval between the plurality of side portion fins 36B. Therefore, in a case where the air flows along the longitudinal direction of the bottom plate 32 from the head portion 38 side between the plurality of fins 36, a pressure loss of first air flowing through the center portion 38A of the head portion 38 is smaller than a pressure loss of second air flowing through the side portion 38B of the head portion 38.

For example, the plurality of fins 36 have a pressure loss structure 46 in which the pressure loss of the first air flowing through the center portion 38A of the head portion 38 is smaller than the pressure loss of the second air flowing through the side portion 38B of the head portion 38. Hereinafter, the pressure loss structure 46 will be described in detail.

For example, the pressure loss structure 46 includes the notch 44 formed in the plurality of fins 36 at the center portion 38A of the head portion 38. In the pressure loss structure 46, the width of each of a plurality of center portion fins 36A is equal to the width of each of the plurality of side portion fins 36B, and the height of each of the plurality of center portion fins 36A is equal to the height of each of the plurality of side portion fins 36B. On the other hand, in the pressure loss structure 46, the interval between the plurality of center portion fins 36A is wider than the interval between the plurality of side portion fins 36B.

By applying the pressure loss structure 46 having the configuration described above to the plurality of fins 36, the pressure loss of the first air flowing through the center portion 38A of the head portion 38 is smaller than the pressure loss of the second air flowing through the side portion 38B of the head portion 38.

Hereinafter, actions and effects of the present embodiment will be described.

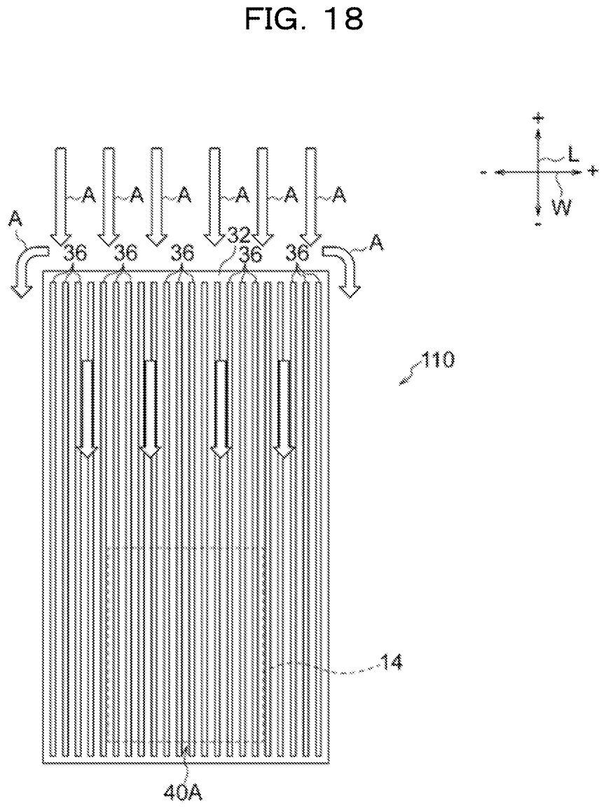

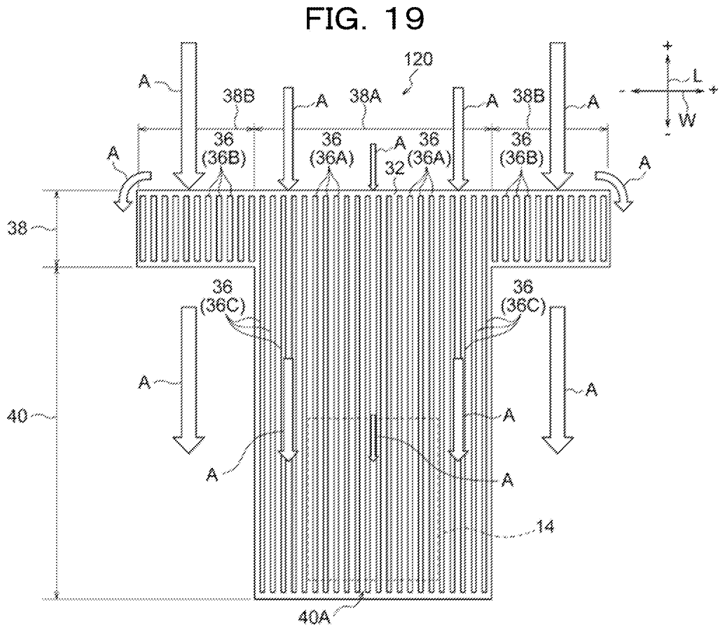

First, a heat sink 110 according to a first comparative example and a heat sink 120 according to a second comparative example will be described with reference to FIGS. 18 and 19 in order to clarify the actions and effects of the present embodiment. Hereinafter, in order to easily understand configurations of the heat sink 110 according to the first comparative example and the heat sink 120 according to the second comparative example, in the heat sink 110 according to the first comparative example and the heat sink 120 according to the second comparative example, the same reference signs are used for the configurations having the same names as the configuration in the present embodiment.

As an example, as illustrated in FIG. 18, in the heat sink 110 according to the first comparative example, the bottom plate 32 is formed to have the same width in the longitudinal direction. A total length of the bottom plate 32 is the same as the total length in the present embodiment. A plurality of fins 36 are arranged in the lateral direction of the bottom plate 32. The plurality of fins 36 extend in the longitudinal direction of the bottom plate 32 from a front end portion to a rear end portion of the bottom plate 32. A coupling region 40A thermally coupled to the heat generation element 14 is provided at a portion of the bottom plate 32 closer to a rear end portion side than a center portion in the longitudinal direction.

In the heat sink 110 according to the first comparative example, the bottom plate 32 and the plurality of fins 36 extend toward an upstream side in an air flow direction with respect to the coupling region 40A. Therefore, it is possible to increase a surface area of the heat sink 16, as compared with a configuration in which the bottom plate 32 and the plurality of fins 36 do not extend to the upstream side in the air flow direction with respect to the coupling region 40A.

Meanwhile, in the heat sink 110 according to the first comparative example, since the plurality of fins 36 extend toward the upstream side in the air flow direction, a pressure loss in external regions on both sides of the heat sink 16 in the lateral direction is smaller than a pressure loss between the plurality of fins 36. Therefore, most of air supplied from a front side of the heat sink 16 to the heat sink 16 flows along the longitudinal direction of the bottom plate 32 through the both sides of the heat sink 16 in the lateral direction. Therefore, since the air flows while avoiding the coupling region 40A, cooling performance for the heat generation element 14 is low.

Next, the heat sink 120 according to the second comparative example will be described. As an example, as illustrated in FIG. 19, in the heat sink 120 according to the second comparative example, the notch 44 is omitted from the heat sink 16 according to the present embodiment. The plurality of center portion fins 36A are erected at the center portion 38A of the head portion 38. The plurality of center portion fins 36A are formed continuously with each of the plurality of body portion fins 36C.

In the heat sink 120 according to the second comparative example, the plurality of center portion fins 36A formed continuously with each of the plurality of body portion fins 36C are erected at the center portion 38A of the head portion 38. On the other hand, each side portion 38B of the head portion 38 projects toward both sides of the body portion 40 in the lateral direction, and the body portion fin 36C is not provided on a rear side of the plurality of side portion fins 36B. Therefore, a pressure loss of first air flowing through the center portion 38A of the head portion 38 is larger than a pressure loss of second air flowing through the side portion 38B of the head portion 38. Therefore, since inflow of air to each side portion 38B of the head portion 38 is promoted, a flow rate in each side portion 38B of the head portion 38 is higher than a flow rate in the center portion 38A of the head portion 38. Therefore, since the air flows while avoiding the coupling region 40A, cooling performance for the heat generation element 14 is low.

By contrast, in the heat sink 16 according to the present embodiment illustrated in FIG. 5, the plurality of fins 36 have the pressure loss structure 46 in which the pressure loss of the first air flowing through the center portion 38A of the head portion 38 is smaller than the pressure loss of the second air flowing through the side portion 38B of the head portion 38. Therefore, since inflow of air to the center portion 38A of the head portion 38 is promoted, a flow rate in the center portion 38A of the head portion 38 is higher than a flow rate in each side portion 38B of the head portion 38. Accordingly, since the air flows toward the coupling region 40A, it is possible to improve the cooling performance for the heat generation element 14, as compared with the first comparative example and the second comparative example.

The pressure loss structure 46 includes the notch 44 formed at the plurality of fins 36 at the center portion 38A of the head portion 38. Therefore, for example, as compared to a case where a flow rate adjusting plate or the like for adjusting the flow rate is used, the inflow of the air to the center portion 38A of the head portion 38 may be promoted with the simple configuration.

The notch 44 is formed in a rectangular shape. Therefore, lengths of the plurality of body portion fins 36C extending to the notch 44 may be made equal to each other. Accordingly, since members used for the plurality of body portion fins 36C may be commonized, a cost of the heat sink 16 may be reduced, as compared with a case where the lengths of the plurality of body portion fins 36C are different.

The plurality of fins 36 include the plurality of center portion fins 36A, the plurality of side portion fins 36B, and the plurality of body portion fins 36C. Therefore, for example, as compared with a configuration including only a configuration corresponding to the plurality of center portion fins 36A and the plurality of body portion fins 36C, the surface areas of the heat sink 16 are increased, so that it is possible to improve the cooling performance for the heat generation element 14.

The interval between the plurality of center portion fins 36A is wider than the interval between the plurality of side portion fins 36B. Accordingly, even when respective widths and respective heights of the center portion fins 36A and the side portion fins 36B are respectively the same, the pressure loss of the first air flowing through the center portion 38A of the head portion 38 may be smaller than the pressure loss of the second air flowing through the side portion 38B of the head portion 38.

The pair of center portion fins 36A are formed continuously with the body portion fins 36C located at both ends among the plurality of body portion fins 36C. Therefore, for example, the cost of the heat sink 16 may be reduced, as compared with a case where the center portion fin 36A is separate from the body portion fin 36C.

The pair of center portion fins 36A are disposed at both end portions of the center portion 38A of the head portion 38. Therefore, since the pair of center portion fins 36A function as guide fins that guide air flowing into the center portion 38A of the head portion 38 toward the body portion 40 side, it is possible to promote the inflow of the air into the body portion 40.

The interval between the plurality of side portion fins 36B is narrower than an interval between the plurality of body portion fins 36C. Accordingly, for example, as compared with a case where the interval between the plurality of side portion fins 36B is equal to the interval between the plurality of body portion fins 36C or wider than the interval between the plurality of body portion fins 36C, it is possible to promote the inflow of the air into the body portion 40.

The plurality of storage devices 20 are disposed at both sides of the body portion 40 in the lateral direction. Therefore, it is possible to avoid that each side portion 38B of the head portion 38 interferes with the plurality of storage devices 20.

Next, modification examples of the present embodiment will be described.

### First Modification Example

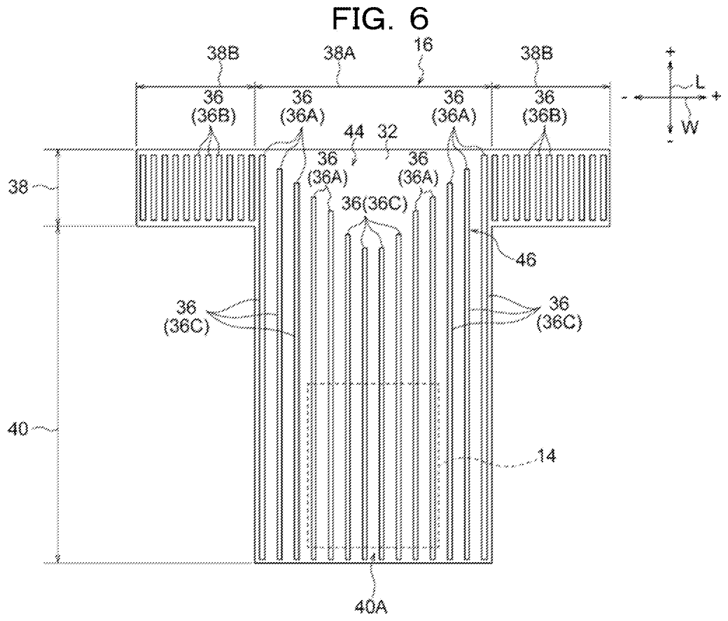

With the embodiment described above, the notch 44 is formed in a rectangular shape. Meanwhile, as illustrated in FIG. 6 as an example, the notch 44 may be formed in a V-shape. With this configuration, a pressure loss is decreased from each side portion 38B toward the center portion 38A of the head portion 38. Therefore, for example, as compared with a case where the notch 44 is formed in a rectangular shape, it is possible to further promote the inflow of air to the center portion of the body portion 40. Accordingly, since a larger amount of air flows toward the coupling region 40A, it is possible to improve cooling performance for the heat generation element 14.

### Second Modification Example

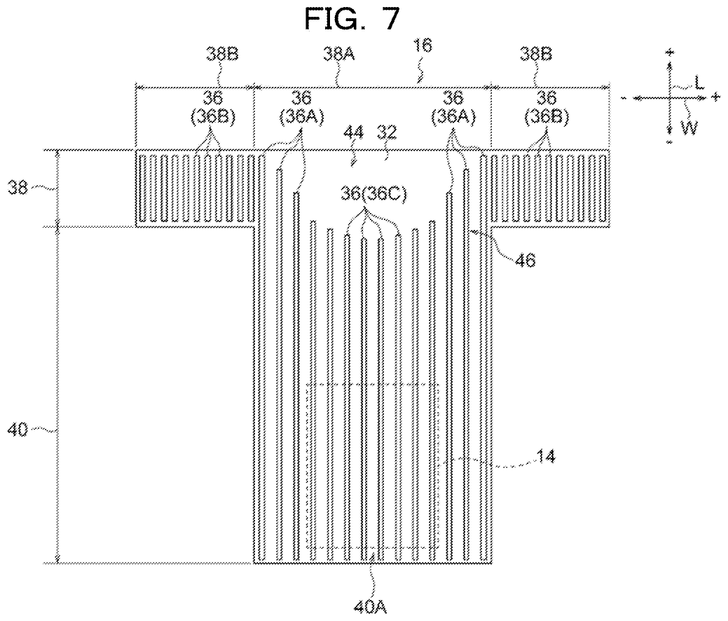

As an example, as illustrated in FIG. 7, the notch 44 may be formed in a U-shape. Also with such a configuration, in the same manner as the case where the notch 44 is formed in the V-shape, the pressure loss is decreased from each side portion 38B toward the center portion 38A of the head portion 38. Therefore, for example, as compared with a case where the notch 44 is formed in a rectangular shape, it is possible to further promote the inflow of air to the center portion of the body portion 40. Accordingly, since a larger amount of air flows toward the coupling region 40A, it is possible to improve cooling performance for the heat generation element 14.

### Third Modification Example

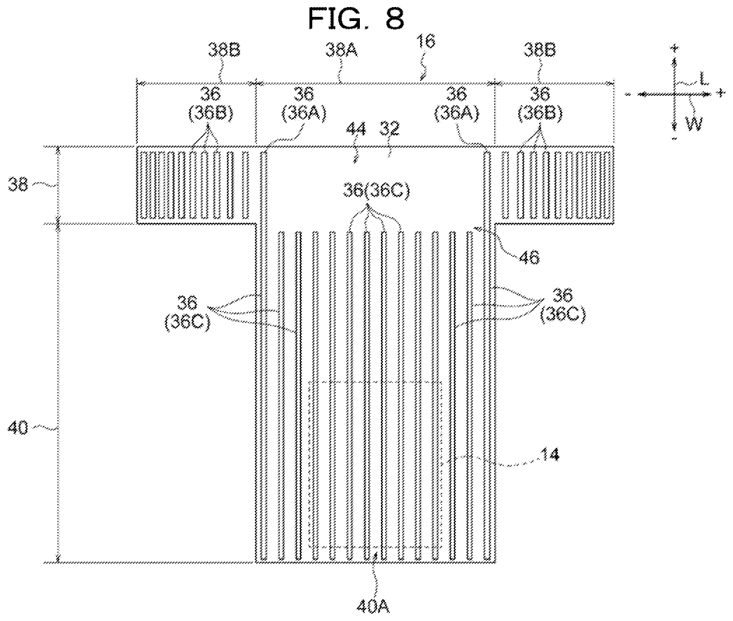

With the embodiment described above, the intervals between the plurality of side portion fins 36B are the same. Meanwhile, as illustrated in FIG. 8 as an example, the intervals between the plurality of side portion fins 36B may become wider toward the center portion 38A side of the head portion 38. With this configuration, in each side portion 38B of the head portion 38, the pressure loss is decreased toward the center portion 38A side of the head portion 38. Therefore, for example, as compared with a case where the intervals between the plurality of side portion fins 36B are the same, it is possible to further promote the inflow of air to the center portion of the body portion 40. Accordingly, since a larger amount of air flows toward the coupling region 40A, it is possible to improve cooling performance for the heat generation element 14.

### Fourth Modification Example

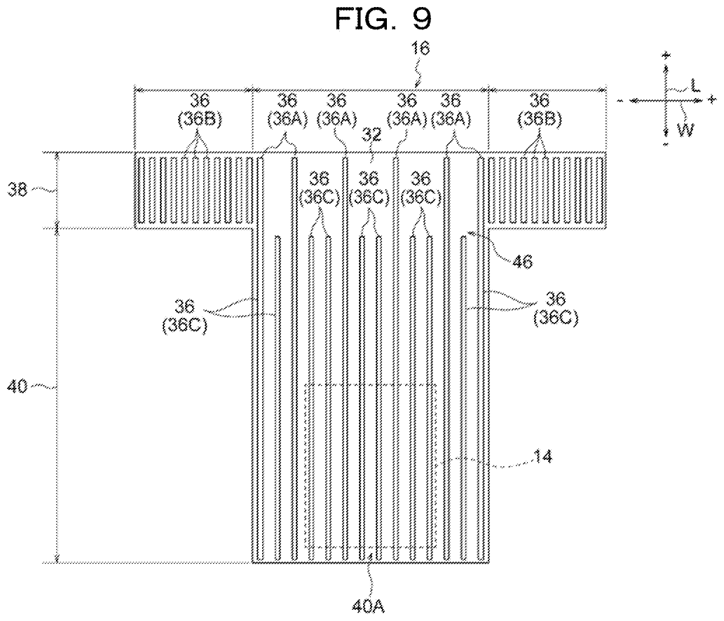

With the embodiment described above, the pair of center portion fins 36A are provided at both end portions of the center portion 38A of the head portion 38. Meanwhile, as an example, as illustrated in FIG. 9, the plurality of other center portion fins 36A may be provided between the pair of center portion fins 36A provided at both end portions of the center portion 38A of the head portion 38, in the center portion 38A of the head portion 38. In the example illustrated in FIG. 9, the number of the plurality of center portion fins 36A is smaller than the number of the plurality of body portion fins 36C. The interval between the plurality of center portion fins 36A is wider than the interval between the plurality of side portion fins 36B. Also with such a configuration, it is possible to make the pressure loss of the first air flowing through the center portion 38A of the head portion 38 smaller than the pressure loss of the second air flowing through the side portion 38B of the head portion 38.

### Fifth Modification Example

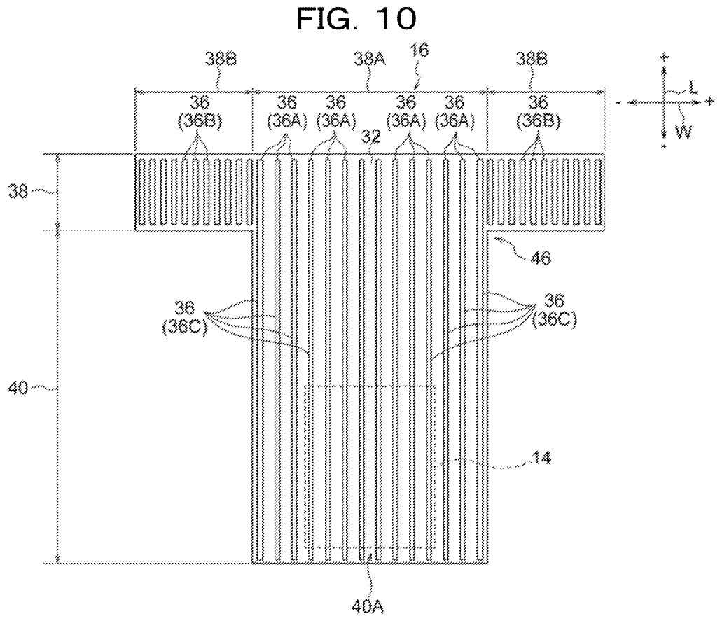

As an example, as illustrated in FIG. 10, the number of the plurality of center portion fins 36A may be the same as the number of the plurality of body portion fins 36C. In this case, the interval between the plurality of center portion fins 36A may be wider than the interval between the plurality of side portion fins 36B. Also with such a configuration, it is possible to make the pressure loss of the first air flowing through the center portion 38A of the head portion 38 smaller than the pressure loss of the second air flowing through the side portion 38B of the head portion 38.

### Sixth Modification Example

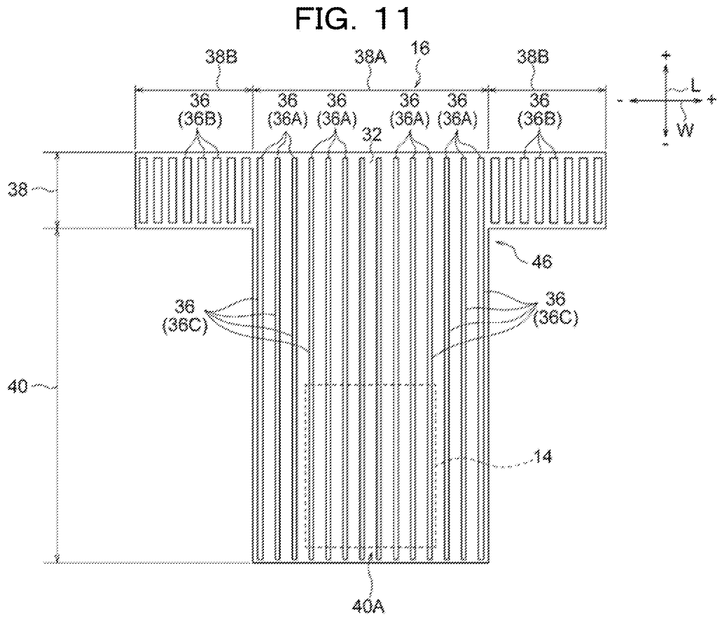

With the embodiment described above, a width of each of the plurality of center portion fins 36A is the same as a width of each of the plurality of side portion fins 363. Meanwhile, as an example, as illustrated in FIG. 11, the width of each of the plurality of center portion fins 36A may be narrower than the width of each of the plurality of side portion fins 363. Also with such a configuration, it is possible to make the pressure loss of the first air flowing through the center portion 38A of the head portion 38 smaller than the pressure loss of the second air flowing through the side portion 383 of the head portion 38.

### Seventh Modification Example

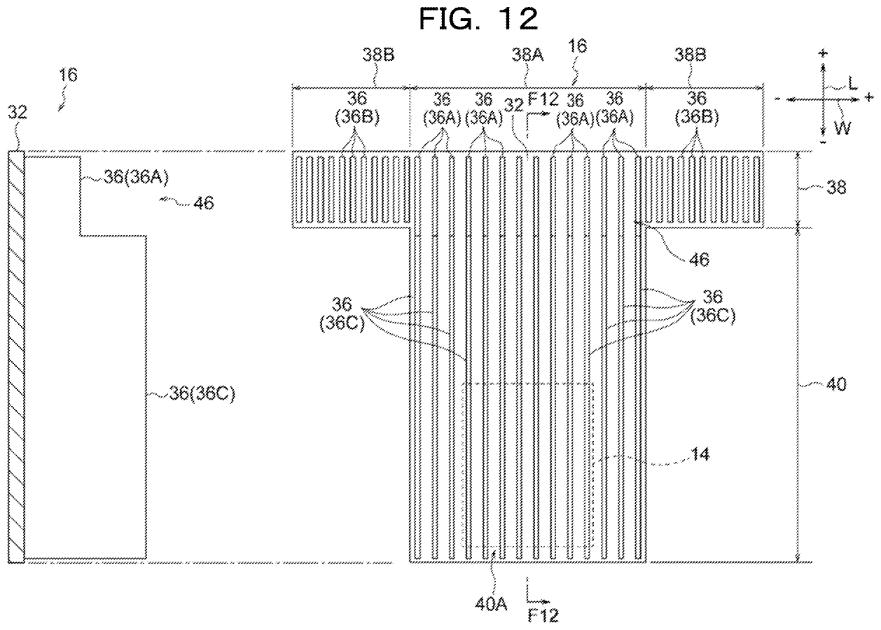

With the embodiment described above, the heights of the plurality of center portion fins 36A and the plurality of side portion fins 36B are equal to each other. Meanwhile, as illustrated in FIG. 12 as an example, for example, in a configuration in which the number of the plurality of center portion fins 36A is the same as the number of the plurality of body portion fins 36C, the height of the plurality of center portion fins 36A may be lower than the height of the plurality of side portion fins 36B. Also with such a configuration, it is possible to make the pressure loss of the first air flowing through the center portion 38A of the head portion 38 smaller than the pressure loss of the second air flowing through the side portion 383 of the head portion 38. The heights of the plurality of center portion fins 36A may be different from each other, and the heights of the plurality of side portion fins 36B may be different from each other.

### Eighth Modification Example

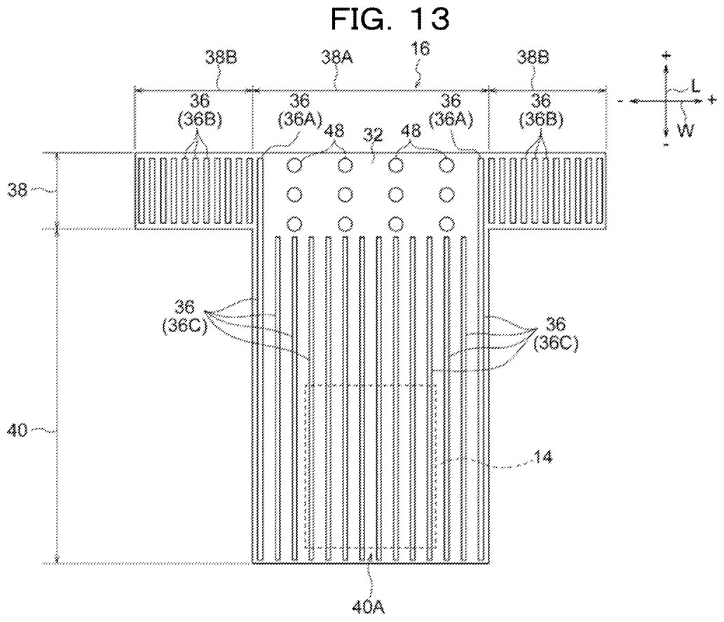

With the embodiment described above, the notch 44 is formed in the plurality of fins 36, and the fins 36 are not disposed inside the notch 44. Meanwhile, as illustrated in FIG. 13, a plurality of pins 48 may be disposed inside the notch 44, instead of the fins 36.

### Ninth Modification Example

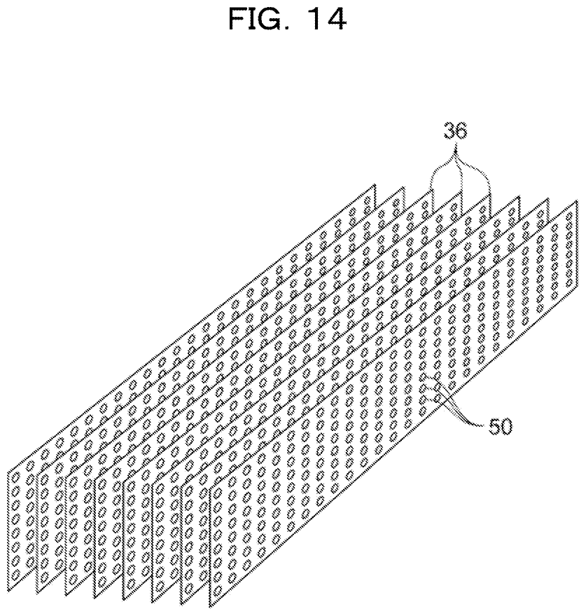

As an example, as illustrated in FIG. 14, in the embodiment described above, the plurality of fins 36 may include the fin 36 having a plurality of projection portions 50 formed at a surface of the fin 36. The fin 36 having the plurality of projection portions 50 formed at the surface may be any portion of the plurality of fins 36. With this configuration, a surface area of the fin 36 may be increased by the plurality of projection portions 50, and turbulence may be generated. Accordingly, the cooling performance for the heat generation element 14 may be improved.

### Tenth Modification Example

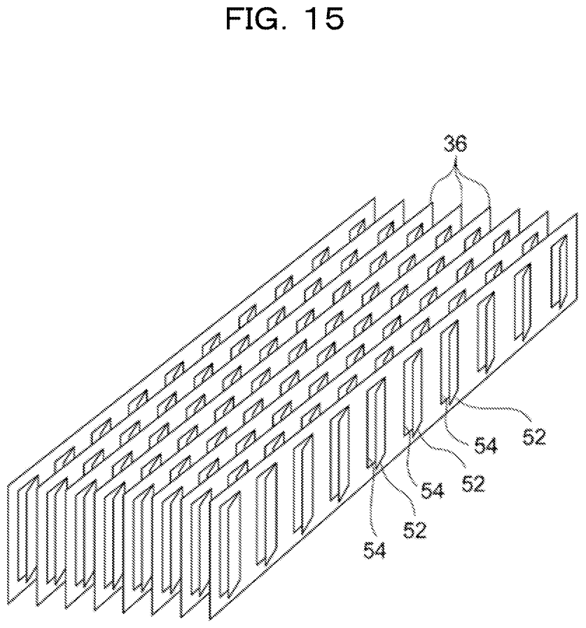

As an example, as illustrated in FIG. 15, in the embodiment described above, the plurality of fins 36 may include the fin 36 having louvers 52. Although the louver 52 is, for example, a cut-and-raised piece formed in the fin 36, the louver 52 may be a member added to the fin 36. In a case where the louver 52 is the cut-and-raised piece, the opening 54 is formed in the fin 36. The fin 36 having the louvers 52 may be any portion of the plurality of fins 36. With this configuration, turbulence may be generated by the louver 52. In a case where the louver 52 is the member added to the fin 36, a surface area of the fin 36 may be increased. Accordingly, the cooling performance for the heat generation element 14 may be improved.

### Eleventh Modification Example

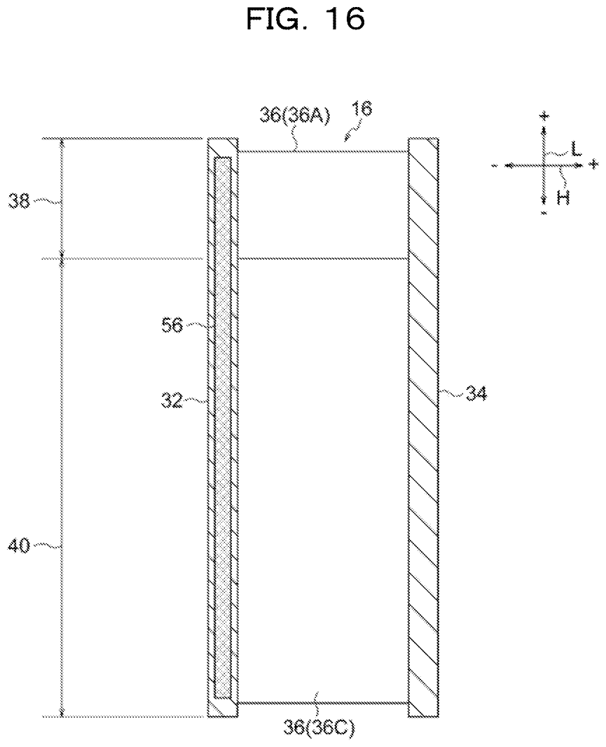

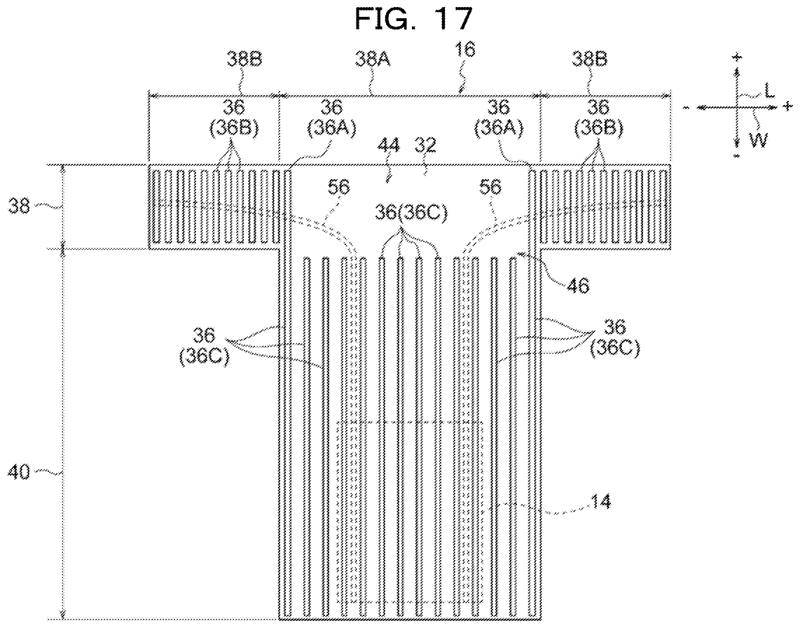

As an example, as illustrated in FIG. 16, in the embodiment described above, a heat transport device 56 that transports heat may be provided at the bottom plate 32. One heat transport device 56 or a plurality of heat transport devices 56 may be provided. The heat transport device 56 may be built in the bottom plate 32 or may be provided outside the bottom plate 32. As an example, as illustrated in FIG. 17, the bottom plate 32 may be provided with a pair of heat transport devices 56 extending from the body portion 40 toward each side portion 38B of the head portion 38. The heat transport device 56 is a device including a container in which a refrigerant is sealed, and is, for example, a vapor chamber, a heat pipe, or the like. With this configuration, heat of the body portion 40 may be transported to the side portion of the head portion 38 by the heat transport device 56, so that the cooling performance for the heat generation element 14 may be improved.

### Other Modification Examples

Although the electronic apparatus 10 is a server in the embodiment described above, the electronic apparatus 10 may be a device other than the server.

Although the electronic apparatus 10 is disposed such that the height direction is the vertical direction in the embodiment described above, the electronic apparatus 10 may be disposed such that the height direction is the horizontal direction.

Although the coupling region 40A thermally coupled to the heat generation element 14 is located on a rear side of the center portion of the body portion 40 in the longitudinal direction in the embodiment described above, the coupling region 40A may be located at the center portion of the body portion 40 in the longitudinal direction.

Although the plurality of side portion fins 36B provided at the side portion 38B of the head portion 38 extend along the longitudinal direction of the bottom plate 32 in the embodiment described above, the plurality of side portion fins 36B may be inclined with respect to the longitudinal direction of the bottom plate 32 so as to face toward the center portion 38A of the head portion 38 from the front end side to the rear end side of the bottom plate 32.

Although the heat sink 16 is configured to be symmetric in the lateral direction in the embodiment described above, the heat sink 16 may be configured to be asymmetric in the lateral direction.

Although the heat sink 16 includes the top plate 34 in the embodiment described above, the top plate 34 may be omitted.

With the embodiment described above, a length of the body portion 40 in the longitudinal direction of the bottom plate 32 may be shorter than a length of the head portion 38.

Among the plurality of modification examples described above, combinable modification examples may be combined as appropriate.

The embodiment of the technique disclosed in the present application has been described above. However, of course, the technique disclosed in the present application is not limited to the above description, and various modifications other than the above description may be made without departing from the gist thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be under stood that the various changes, substitutions, and alterations could be made hereto without departing from the spirit and scope of the invention.

What is claimed is:

1. A heat sink comprising:
a bottom plate that is formed in a T-shape of a head portion and a body portion and includes a coupling region in which the body portion is thermally coupled to a heat generation element; and
a plurality of fins that are erected at the head portion and the body portion of the bottom plate and extend in a direction from the head portion toward the body portion,
wherein with the plurality of fins, a pressure loss of first air which flows through a center portion of the head portion is smaller than a pressure loss of second air which flows through a side portion of the head portion in a case where air flows between the plurality of fins along the direction.

2. The heat sink according to claim 1,
wherein the plurality of fins include a notch formed at the plurality of fins at the center portion of the head portion.

3. The heat sink according to claim 2,
wherein the notch is formed in a rectangular shape.

4. The heat sink according to claim 2,
wherein the notch is formed in a V-shape.

5. The heat sink according to claim 2,
wherein the notch is formed in a U-shape.

6. The heat sink according to claim 1,
wherein the plurality of fins include
a plurality of center portion fins erected at the center portion of the head portion,
a plurality of side portion fins erected at the side portion of the head portion, and
a plurality of body portion fins erected at the body portion.

7. The heat sink according to claim 6,
wherein in the plurality of fins, an interval between the plurality of center portion fins is wider than an interval between the plurality of side portion fins.

8. The heat sink according to claim 6,
wherein in the plurality of fins, a width of each of the plurality of center portion fins is narrower than a width of each of the plurality of side portion fins.

9. The heat sink according to claim 6,
wherein in the plurality of fins, a height of the plurality of center portion fins is lower than a height of the plurality of side portion fins.

10. The heat sink according to claim 6,
wherein the plurality of center portion fins are formed continuously with the plurality of body portion fins.

11. The heat sink according to claim 6,
wherein the plurality of center portion fins are disposed at both end portions of the center portion of the head portion.

12. The heat sink according to claim 6,
wherein an interval between the plurality of side portion fins is narrower than an interval between the plurality of body portion fins.

13. The heat sink according to claim 6,
wherein an interval between the plurality of side portion fins becomes wider toward a center of the head portion.

14. The heat sink according to claim 1,
wherein the plurality of fins include a fin which has a surface at which a plurality of projection portions are formed.

15. The heat sink according to claim 1,
wherein the plurality of fins include a fin which has a louver.

16. The heat sink according to claim 1, further comprising:
a heat transport device that is provided at the bottom plate and transports heat.

17. The heat sink according to claim 16,
wherein the heat transport device extends from the body portion to the side portion of the head portion.

18. An electronic apparatus comprising:
a heat generation element;
a heat sink; and
one or more fans;
wherein the heat sink including:
a bottom plate that is formed in a T-shape of a head portion and a body portion and includes a coupling region in which the body portion is thermally coupled to the heat generation element; and
a plurality of fins that are erected at the head portion and the body portion of the bottom plate and extend in a direction from the head portion toward the body portion,
wherein with the plurality of fins, a pressure loss of first air which flows through a center portion of the head portion is smaller than a pressure loss of second air which flows through a side portion of the head portion in a case where air caused by the fans flows between the plurality of fins along the direction.

19. The electronic apparatus according to claim 18, further comprising a plurality of memory devices provided at both sides of the body portion.
